(19) United States
(12) Patent Application Publication
(10) Pub. No.: US 2015/0280111 A1
(43) Pub. Date: Oct. 1, 2015

(54) MAGNETIC MULTILAYER FILM AND TUNNELING MAGNETORESISTANCE ELEMENT

(71) Applicant: NATIONAL INSTITUTE OF ADVANCED INDUSTRIAL SCIENCE AND TECHNOLOGY, Tokyo (JP)

(72) Inventors: Shinji Yuasa, Ibaraki (JP); Takayuki Nozaki, Ibaraki (JP)

(21) Appl. No.: 14/423,978

(22) PCT Filed: Aug. 27, 2013
(86) PCT No.: PCT/JP2013/072812

§ 371 Date: Feb. 25, 2015

(30) Foreign Application Priority Data
Aug. 31, 2012 (JP) 2012-192115

(51) Int. Cl. H01L 43/10; H01L 43/08; H01L 43/02

(52) U.S. Cl. CPC H01L 43/10; H01L 43/02; H01L 43/08

(57) ABSTRACT

A magnetic multilayer film, includes a nonmagnetic layer including a single- or poly-crystalline magnesium oxide in which a (001) crystal plane is preferentially oriented, a very thin layer including an oxide of a 3d transition metal element, and a very thin ferromagnetic layer, laminated in sequence starting on a substrate side.

### TECHNICAL FIELD

The present invention relates to a magnetic multilayer film and a tunnel magnetoresistive element.

### BACKGROUND ART

Spin torque MRAM (magnetoresistive random access memory or magnetic random access memory), which facilitates miniaturization and assures high speed and low power requirement, has been attracting a great deal of attention in recent years as a technology to replace existing non-volatile embedded memory, DRAM and SRAM.

A spin torque MRAM is a storage element designed to take advantage of a phenomenon known as spin torque-induced magnetization reversal, whereby the direction along which a ferromagnetic layer is magnetized is reversed as an electric current is supplied to its unit storage element constituted with a tunnel magnetoresistive element (TMR element) or may otherwise be referred to as a magnetic tunnel junction element (MTJ element). Simply put, a TMR element assumes a structure achieved by enclosing a tunnel barrier layer within two ferromagnetic layers (one of the two ferromagnetic layers may be referred to as a “ferromagnetic lower electrode layer” and the other may be referred to as a “ferromagnetic upper electrode layer”). When an electric current flows from one of the ferromagnetic layers toward the other ferromagnetic layer via the tunnel barrier layer, the tunnel magnetoresistance effect (TMR effect), whereby the resistance at the TMR element is lowered or raised as the directions of magnetization of the two ferromagnetic layers become parallel to each other or anti-parallel to each other, is induced. The TMR element is utilized as a non-volatile magnetic memory by setting the low resistance state and the high resistance state at the TMR element as “1” and “0” in digital information.

While the ferromagnetic layers in earlier TMR elements, developed during the early stages of TMR element research and development, would be magnetized along the film surface as in-plane magnetized, MRAM with perpendicular magnetized manifesting magnetization along a direction perpendicular to the film surface, has been developed in recent years so as to assure higher density.

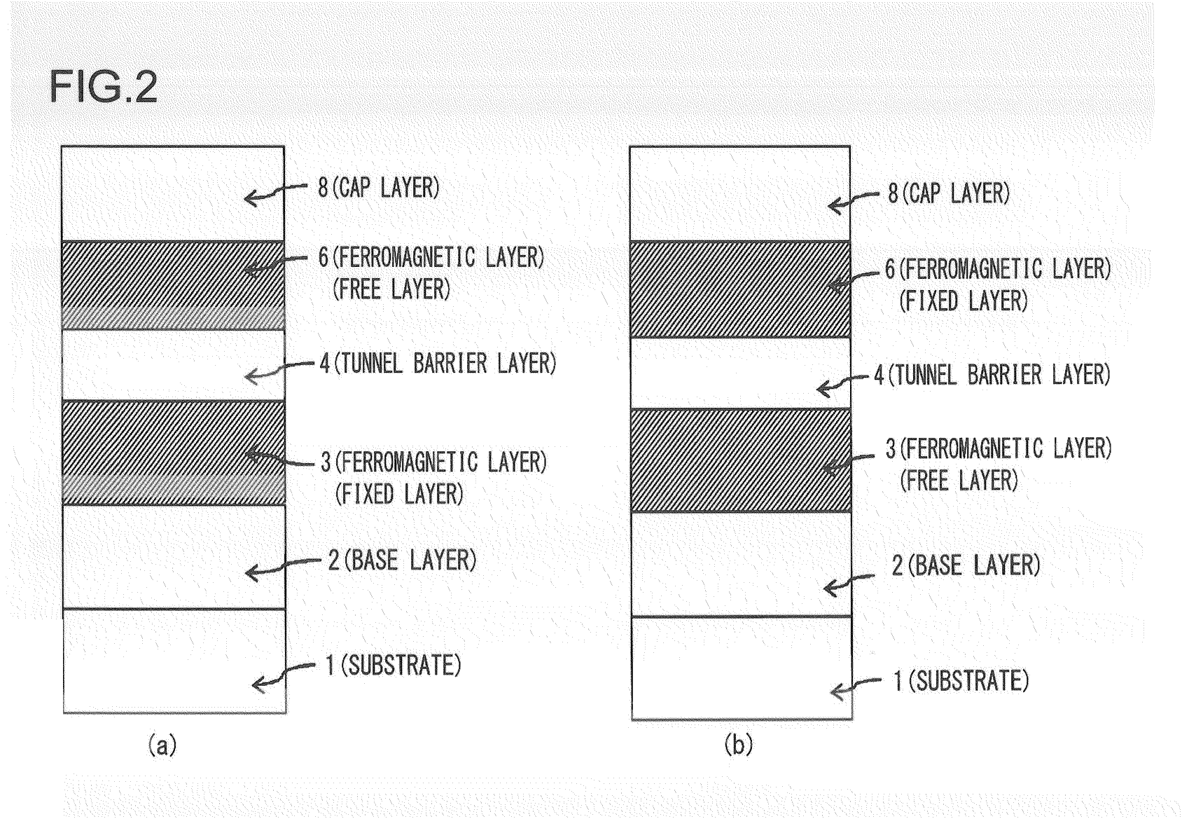

TMR elements optimal for various applications basically adopt a three-layer structure that includes a ferromagnetic layer formed as a free layer (or a recording layer), a tunnel barrier layer and a ferromagnetic layer formed as a fixed layer (pinned layer). The free layer in the three layer structure may be formed at a position further upward relative to the tunnel barrier layer (4) (further away from a substrate 1) as shown in FIG. 2(a) or at a position further downward relative to the tunnel barrier layer (4) (closer to the substrate 1) as shown in FIG. 2(b) based upon a specific rationale. A press release by the National Institute of Advanced Industrial Science and Technology (incorporated administrative agency) on May 13, 2010 announced that a perpendicular magnetized TMR element, which would make it possible to increase the capacity of spin torque MRAMs, had been developed. This element adopts a structure having its free layer disposed at a position lower than the tunnel barrier layer. The element disclosed in patent literature 1 (Japanese Laid Open Patent Publication No. 2007-059927, Toshiba), in contrast, includes a free layer disposed further upward relative to the tunnel barrier layer.

### CITATION LIST

### Patent Literature

PTL1: Japanese Laid Open Patent Publication No. 2007-059927

### NON-PATENT LITERATURE

NPL1: Press release from the National Institute of Advanced Industrial Science and Technology (incorporated administrative agency) dated May 13, 2010, entitled “Perpendicular Magnetized TMR Element Making it Possible to Increase the Capacity of Spin-RAMs (MRAMs)”

### SUMMARY OF INVENTION

### Technical Problem

In principle, it is desirable that the ferromagnetic layer formed as the free layer in a TMR element to be utilized as, for instance, a storage element or a high-frequency oscillation element in a spin torque MRAM should be thin for the following reasons 1 and 2. In addition, the free layer may assume a multilayer structure made up with two or more layers for various reasons, and in such a case, too, it is desirable that the multilayer structure, and the first ferromagnetic layer disposed in contact with the tunnel barrier layer in particular, have a small thickness for the same reasons.

(Reason 1) Depending upon the exact purpose of use for the element, 1) The electric current density required to induce spin torque magnetization reversal, or 2) the electric current density required to induce high-frequency oscillation is invariably lower when the thickness of the free layer is smaller. Such a reduction in the electric current density will lead to reduced power requirement and/or higher density and will also be effective in improving the long-term reliability of the element. This means that basically, it is better to aim for lower electric current density.
(Reason 2) With a thinner free layer, the extent of magneto-static coupling occurring between the free layer and the fixed layer can be lowered. Generally speaking, a significant extent of magneto-static coupling tends to give rise to problems such as the inability to sustain binary stability near the 0 magnetic field at the MRAM to result in unstable element operation. In addition, when numerous TMR elements are disposed on a single substrate in a matrix pattern in memory applications such as MRAM, a magnetic field leak from the free layer in a given element to the free layer at an adjacent element tends to occur. A significant magnetic field leak gives rise to various problems such as unstable information rewriting operations at the adjacent element. It is thus desirable, from the viewpoint of practical use, to reduce the thickness of the free layer, since the extent of magnetic field leak is reduced when the free layer is thinner.

Material deemed superior for the tunnel barrier layer is a single- or poly-crystalline magnesium oxide, in which of both a (001) crystal plane is preferentially oriented (hereafter may be simply referred to as a “magnesium oxide (001)”), and these materials are already utilized in practical applications. Tunnel barrier layers containing amorphous aluminum oxide or amorphous titanium oxide, instead of magnesium oxide, are also utilized in practical applications. However, the “magnesium oxide (001)” is superior to these amorphous materials in that it demonstrates a very significant TMR effect.

As described above, the basic TMR element structures include the following two:

(i) a structure that includes a fixed layer (ferromagnetic layer) disposed closer to the substrate relative to the tunnel barrier layer and a free layer (ferromagnetic layer) disposed further away from the substrate (see FIG. 2(a));
(ii) a structure that includes a free layer (ferromagnetic layer) disposed closer to the substrate relative to the tunnel barrier layer and a fixed layer (ferromagnetic layer) further away from the substrate (see FIG. 2(b)).
The structure (i), assuring advantages such as better ease in element processing and better reliability of the fixed layer, is often adopted in magnetic sensor applications. However, the structure (i) has an issue in that it does not allow the free layer to achieve a small thickness, as will be explained later, and this shortcoming proves to be problematic in applications such as spin torque MRAMs and high-frequency oscillation elements. While the structure (ii) allows the free layer to assume a small thickness, it has issues in that the fixed layer cannot be formed as a thin layer and that the reliability of the fixed layer tends to be readily compromised.

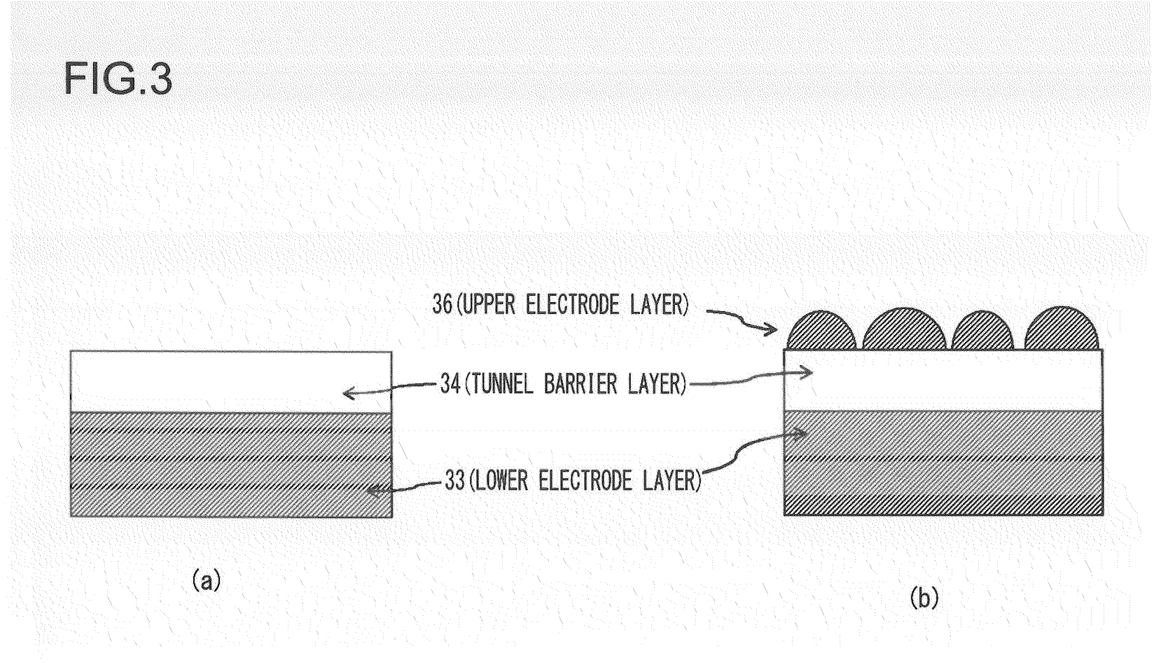

One of the crucial properties required of a material to ensure formation of a superior tunnel barrier is that pinholes are not readily formed in the tunnel barrier layer. Tunnel barrier layers normally assume a very small thickness of approximately 1 to 2 nm, and thus, very small holes, i.e., pinholes, tend to be readily formed. However, even if only a single pinhole is present in a tunnel junction element, a large electric current will flow through the pinhole to result in significant degradation in the element characteristics. In order to form a tunnel barrier layer completely free of pinholes, it is necessary to ensure during the tunnel barrier layer forming process that the tunnel barrier layer completely covers the surface of the ferromagnetic layer (lower electrode layer) present underneath with a high level of efficiency. The term “wettability” is used to refer to these characteristics, and when the tunnel barrier layer completely covers the surface of the ferromagnetic layer (lower electrode layer), “good wettability” is achieved. In order to assure good wettability, the surface energy of the tunnel barrier layer must be much lower than the surface energy of the ferromagnetic layer (lower electrode layer). Generally speaking, a superior tunnel barrier layer material assures extremely low surface energy and thus, good wettability over the ferromagnetic layer (lower electrode layer) is achieved. Consequently, pinholes are not readily formed at the tunnel barrier layer made of such a material (see FIG. 3(a)). At the same time, since the surface energy of the ferromagnetic layer (upper electrode layer) laminated over the tunnel barrier layer becomes to be higher than the surface energy of the tunnel barrier material, the wettability of the ferromagnetic layer (upper electrode layer) laminated over the tunnel barrier layer is bound to be poor. For this reason, a very thin ferromagnetic layer (upper electrode layer) laminated directly upon the tunnel barrier layer tends to form discrete island shaped areas instead of a flat continuous film (see FIG. 3(b)). In other words, when the surface energy of the tunnel barrier layer is lower, it is more difficult to form a very thin ferromagnetic layer (upper electrode layer) as a flat film spread continuously over the tunnel barrier layer. This is a fundamental problem of a good tunnel barrier layer.

A nonmagnetic material containing “magnesium oxide (001)” is a superior tunnel barrier material assuring very low surface energy, and thus, a very high level of wettability is achieved for the tunnel barrier layer made of this nonmagnetic material in relation to the lower ferromagnetic layer. This means that a high quality tunnel barrier layer (4) with no pinholes can be manufactured with this tunnel barrier material. However, since the surface energy of the nonmagnetic layer is much lower than the surface energy of a metal or alloy layer (ferromagnetic layer), the wettability of the metal or alloy layer (ferromagnetic layer) laminated directly onto the nonmagnetic layer is bound to be extremely poor. For this reason, the upper ferromagnetic layer (upper electrode layer) constituted with an extremely thin metal or alloy layer deposited directly upon the nonmagnetic layer tends to form separate island shaped areas instead of a flat continuous film. Generally speaking, a metal or alloy layer (upper ferromagnetic layer) with a thickness less than approximately 1 to 1.5 nm, laminated over the surface of the nonmagnetic layer, will form discontinuous, island shaped film areas. This is the problem to be solved.

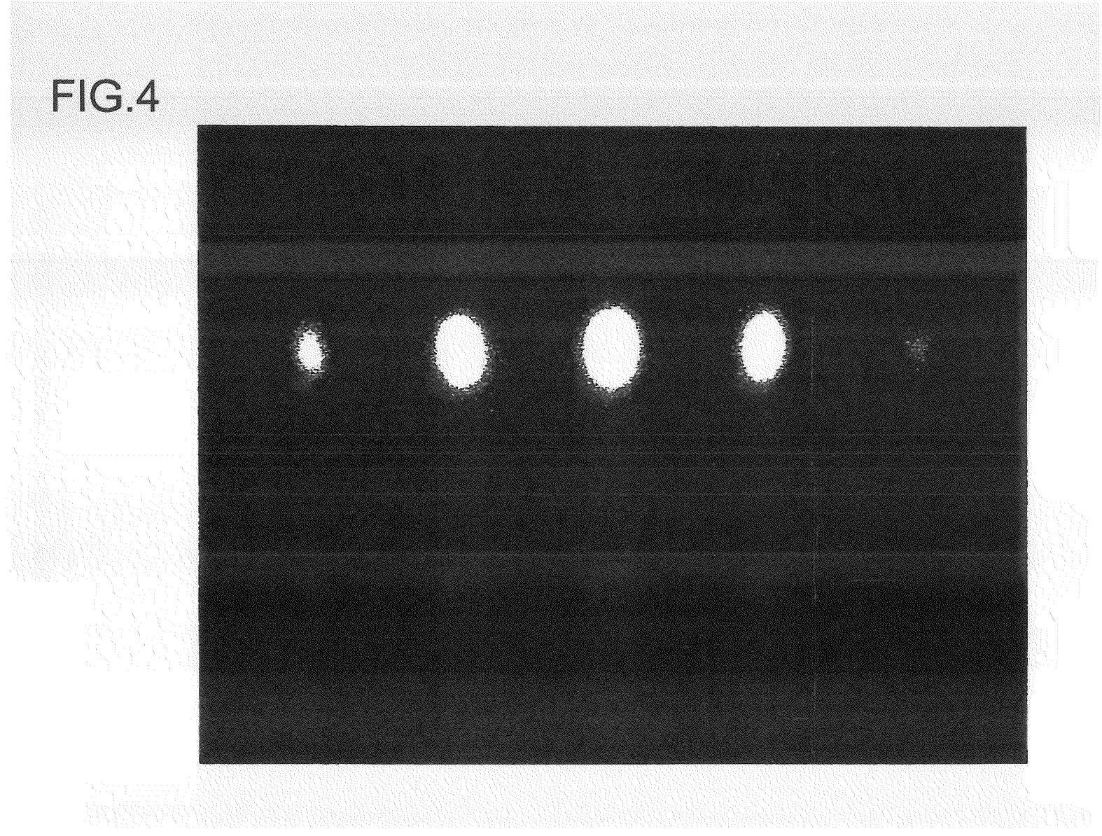

FIG. 4 presents a reflection high-energy electron diffraction (RHEED) image of a very thin Fe layer (an example of a ferromagnetic layer) with a 0.8 nm thickness laminated on the surface of a “magnesium oxide (001)” layer through an ultrahigh vacuum MBE method at room temperature. A spotted diffraction pattern such as this indicates that the Fe layer is formed in island shaped areas. The magnetic characteristics of the Fe layer (ferromagnetic layer) formed over discontinuous, island shaped film areas are bound to be greatly degraded.

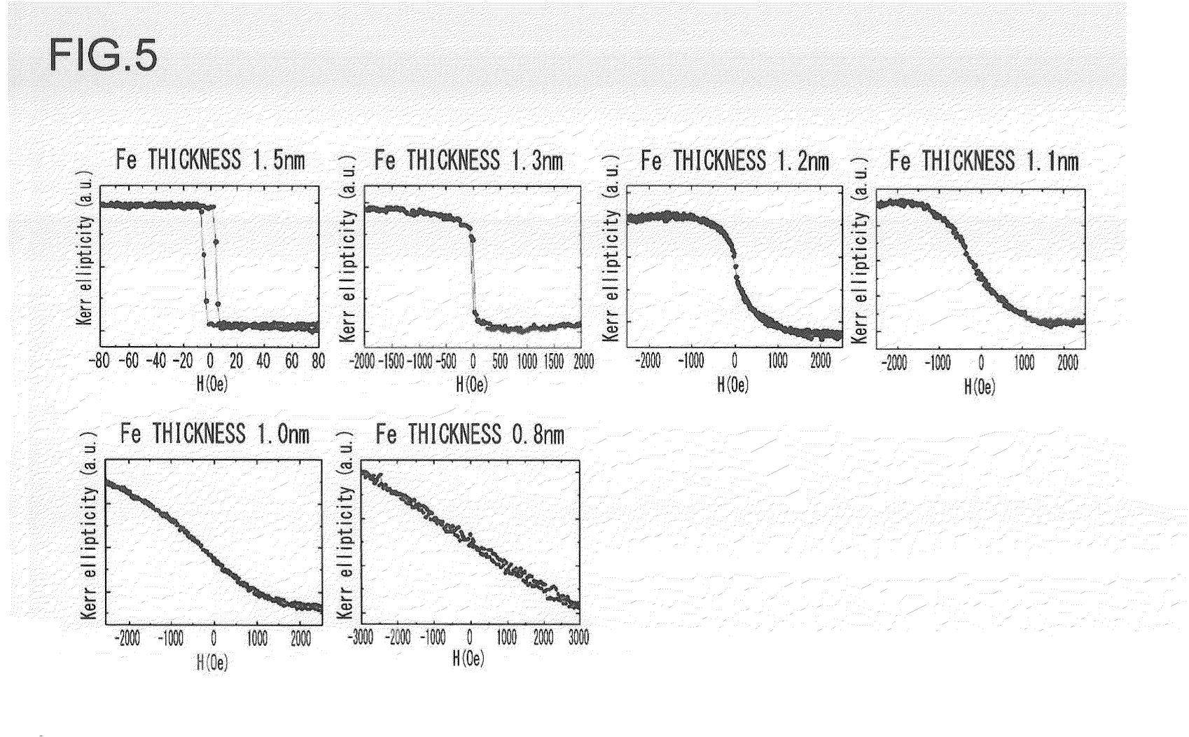

FIG. 5 presents magnetization curves representing magnetization occurring at room temperature in Fe layers (ferromagnetic layers) laminated over the surface of the “magnesium oxide (001)” layer through the MBE method at room temperature, each obtained through magneto-optical Kerr effect measurement. When the thickness of the Fe layer is equal to or less than approximately 1.0 nm, the Fe layer, forming discontinuous, island shaped film areas, manifests superparamagnetism rather than ferromagnetism. The figure indicates that the Fe layer needs to achieve a thickness equal to or greater than approximately 1.5 nm in order to achieve a desirable ferromagnetic magnetization curve with hysteresis.

As described above, it has been extremely difficult to form a high-quality ferromagnetic layer (ferromagnetic upper electrode layer) with a film thickness smaller than approximately 1 nm over a nonmagnetic layer (tunnel barrier layer) constituted of a material containing the “magnesium oxide (001)”. In addition, while the ferromagnetic layer (ferromagnetic upper electrode layer) is often formed as a multilayer film by laminating two or more layers constituted of different material compositions or constituted of materials assuming different crystal structures, it is, in principle, difficult in this case to manufacture the first ferromagnetic layer (part of the ferromagnetic upper electrode layer) located closer to the nonmagnetic layer as a flat continuous film with a thickness less than approximately 1 nm.

### Solution to Problem

The inventor of the present invention et al. fortuitously discovered that much improved wettability, resulting from the presence of a very thin interposed layer of a specific type (an oxide layer comprising 3d transition metal element) formed upon the surface of a “magnesium oxide (001)” layer with poor wettability, effectively solves the problem discussed above and that since the interposed layer is extremely thin, its presence does not significantly degrade the magneto-resistance ratio (MR ratio) of the TMR elements. The inventor of the present invention et al. has conceived the present invention based upon these findings.

The present invention consists of numerous inventions pertaining to a magnetic multilayer film and a TMR element.

The first aspect of the present invention is a magnetic multilayer film, comprises: a nonmagnetic layer comprising a single- or poly-crystalline magnesium oxide in which a (001) crystal plane is preferentially oriented, a very thin layer comprising an oxide of 3d transition metal element, and a very thin ferromagnetic layer, laminated in sequence starting on a substrate side.

The 3d transition metal element may be any of the following ten elements: Sc (scandium), Ti (titanium), V (vanadium), Cr (chromium), Mn (manganese), Fe (iron), Co (cobalt), Ni (nickel), Cu (copper) and Zn (zinc).

It will be obvious that a plurality of these elements may be mixed in the oxide (e.g., Co ferrite). In addition, as long as the essential characteristics of the present invention remain intact, the oxide may be composed by mixing single or a plurality of other elements, or the oxide may include other substance mixed therein.

The second aspect of the present invention is the magnetic multilayer film according to the first aspect, it is preferred that a second ferromagnetic layer, assuming that the ferromagnetic layer is a first ferromagnetic layer, is formed on the first ferromagnetic layer, which second ferromagnetic layer has a composition or a crystal structure different from the first ferromagnetic layer.

The third aspect of the present invention is the magnetic multilayer film according to the first or second aspect, it is preferred that a film thickness of the oxide layer of the 3d transition metal element is 0.2 to 1.5 nm.

The fourth aspect of the present invention is the magnetic multilayer film according to any one of the first through third aspects, it is preferred that the oxide layer of the 3d transition metal element comprises an oxide of at least one element among Fe, Co and Ni.

The fifth aspect of the present invention is the magnetic multilayer film according to any one of the first through fourth aspects, it is preferred that the oxide layer of the 3d transition metal element comprises “an oxide of a 3d transition metal element” with a spinel structure.

The sixth aspect of the present invention is the magnetic multilayer film according to any one of the first through fifth aspects, it is preferred that the oxide layer of the 3d transition metal element comprises a “spinel ferrite-type oxide of a 3d transition metal element”.

The seventh aspect of the present invention is the magnetic multilayer film according to the sixth aspect, it is preferred that the “spinel ferrite-type oxide of a 3d transition metal element” is a ferromagnetic or a ferrimagnetic spinel ferrite type material. The eighth aspect of the present invention is the magnetic multilayer film according to any one of the first through third aspects, it is preferred that the “spinel ferrite-type oxide of a 3d transition metal element” comprises maghemite, magnetite, Co ferrite or Ni ferrite.

The ninth aspect of the present invention is the magnetic multilayer film according to any one of the first through eighth aspects, it is preferred that a film thickness of the ferromagnetic layer or the first ferromagnetic layer is 0.2 to 0.8 nm.

The tenth aspect of the present invention is the magnetic multilayer film according to any one of the first through ninth aspects, it is preferred that the ferromagnetic layer or the first ferromagnetic layer comprises a ferromagnetic metal containing Fe, or a ferromagnetic alloy containing Fe.

The eleventh aspect of the present invention is the magnetic multilayer film according to any one of the first through tenth aspects, it is preferred that the ferromagnetic layer or the first ferromagnetic layer comprises a ferromagnetic metal with a BCC structure containing Fe or Co, or a ferromagnetic alloy with a BCC structure containing Fe or Co.

The twelfth aspect of the present invention is a tunnel magnetoresistive element comprising a ferromagnetic lower electrode layer, a tunnel barrier layer and a ferromagnetic upper electrode layer in sequence starting on a substrate side, wherein the magnetic multilayer film according to any one of the first through eleventh aspects constitutes a component of the tunnel magnetoresistive element, in which the nonmagnetic layer corresponds to the tunnel barrier layer(s) or part thereof, the ferromagnetic layer corresponds to the upper electrode layer(s) or part thereof, or a multilayer laminate made up with the first ferromagnetic layer and the second ferromagnetic layer corresponds to the upper electrode layer(s) or part thereof.

### Advantageous Effect of Invention

According to the present invention, the presence of an interposed layer (an oxide layer comprising an oxide of a 3d transition metal element) makes it possible to form an extremely thin, flat ferromagnetic layer (upper electrode layer) on a nonmagnetic layer (tunnel barrier layer) comprising a single- or poly-crystalline magnesium oxide in which the (001) crystal plane is preferentially oriented. At the same time, the MR ratio will not be degraded to any significant extent in TMR applications.

It is to be noted that in the following description, the “oxide layer comprising an oxide of a 3d transition metal element” may be simply referred to as an “oxide layer”.

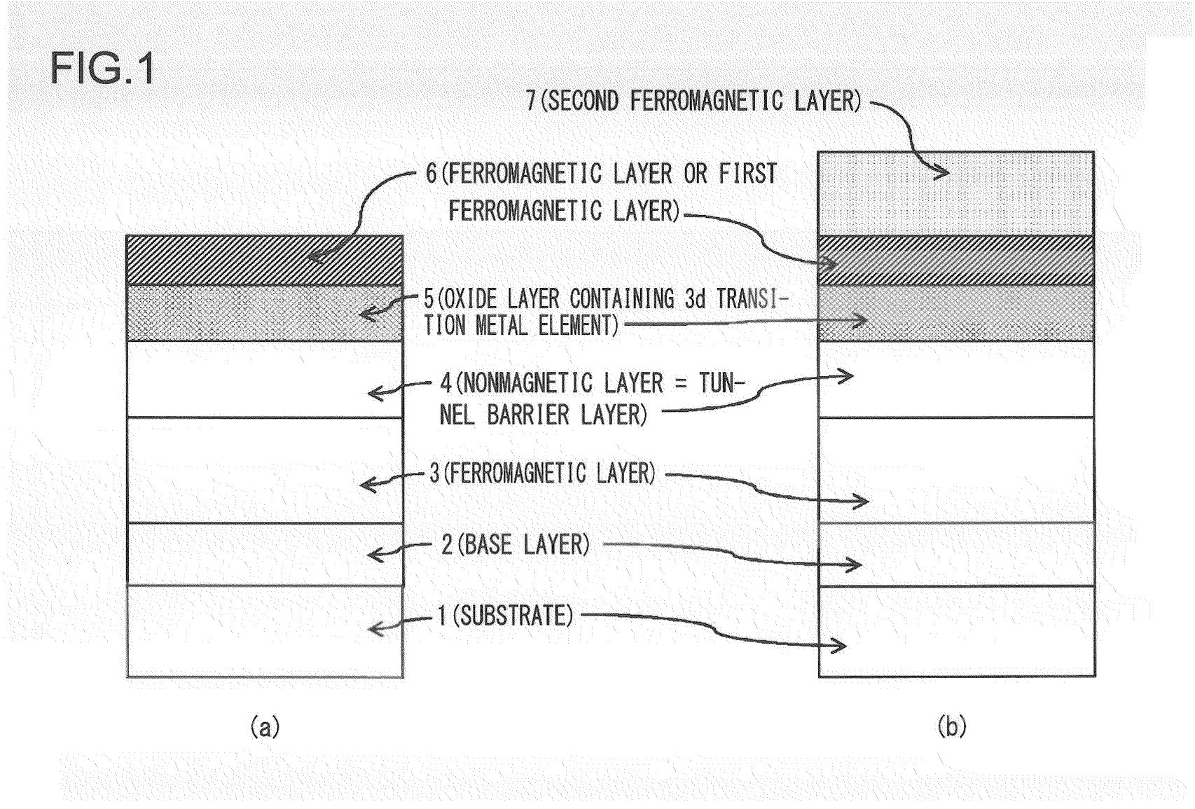

### BRIEF DESCRIPTION OF DRAWINGS

[FIG. 1] FIG. 1(a) shows a schematic sectional view of a magnetic multilayer film and a

TMR element achieved in embodiment 1 and FIG. 1(b) is a schematic sectional view of a magnetic multilayer film and a TMR element achieved in embodiment 2.

[FIG. 2] FIG. 2 shows typical TMR elements in schematic sectional views, with FIG. 2 (a) presenting an example in which a tunnel barrier layer (4) is formed upon the fixed layer and FIG. 2 (b) presenting an example in which a tunnel barrier layer (4) is formed upon the free layer.

[FIG. 3] FIG. 3(a) shows a schematic sectional view of a good tunnel barrier layer (34) formed upon the lower electrode layer (31) and FIG. 3(b) is a schematic sectional view of an upper electrode layer (34) formed with island shaped areas upon the good tunnel barrier layer (34).

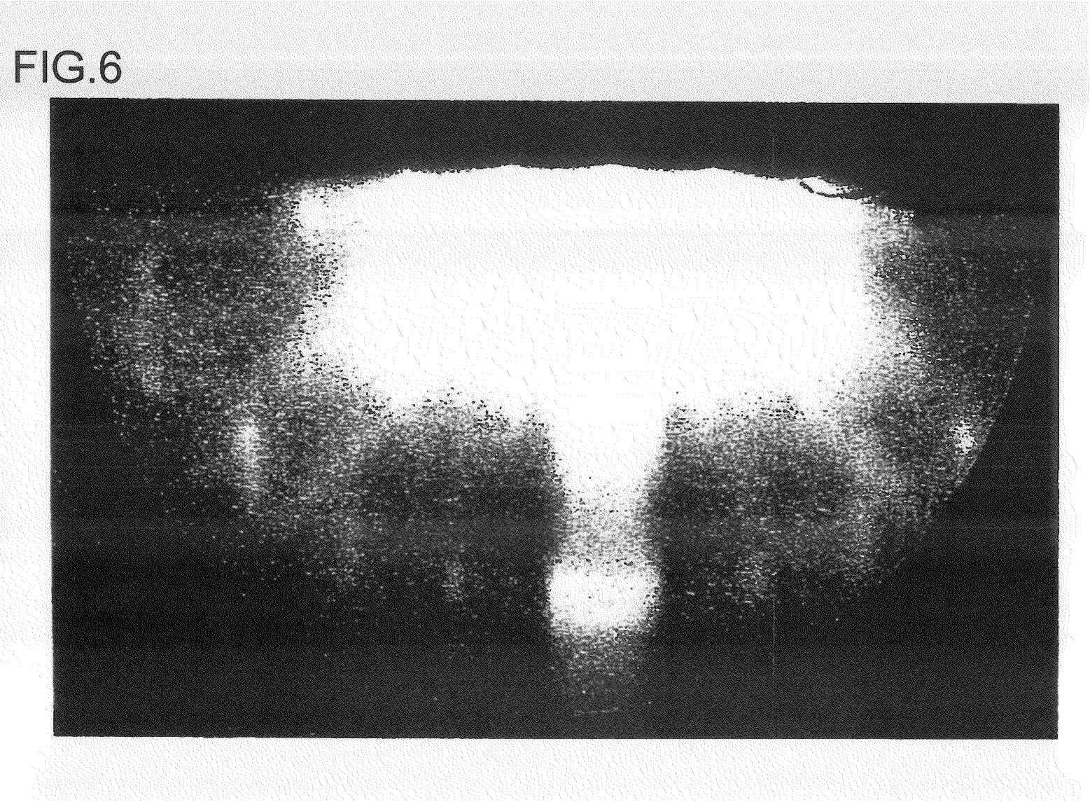

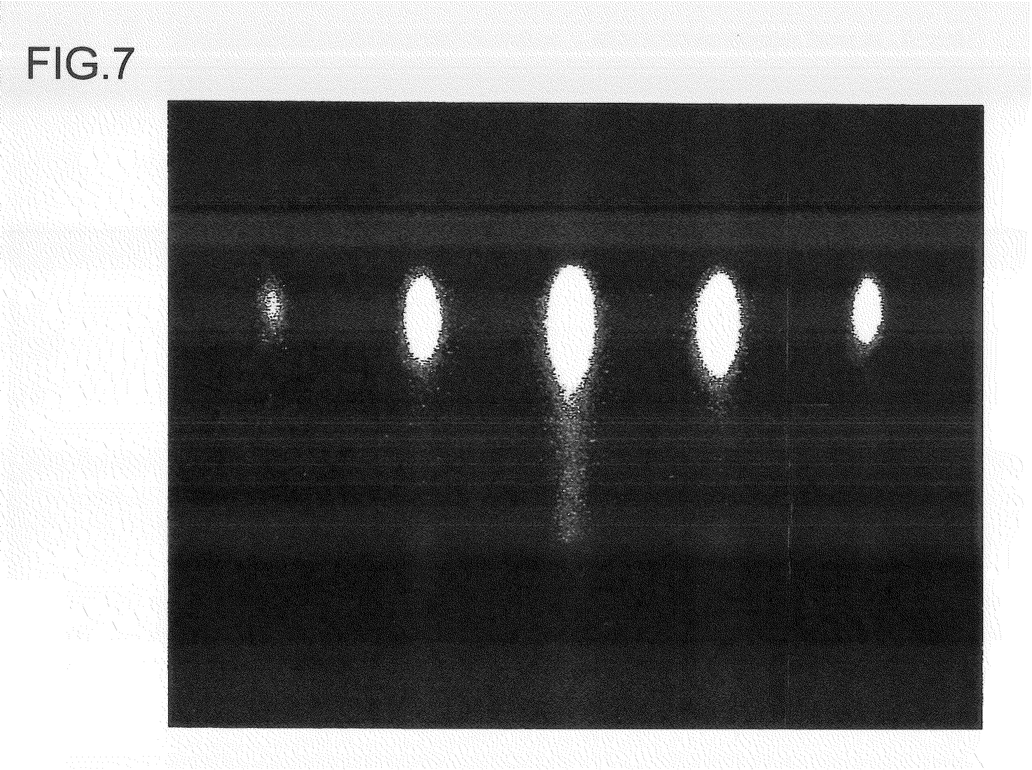

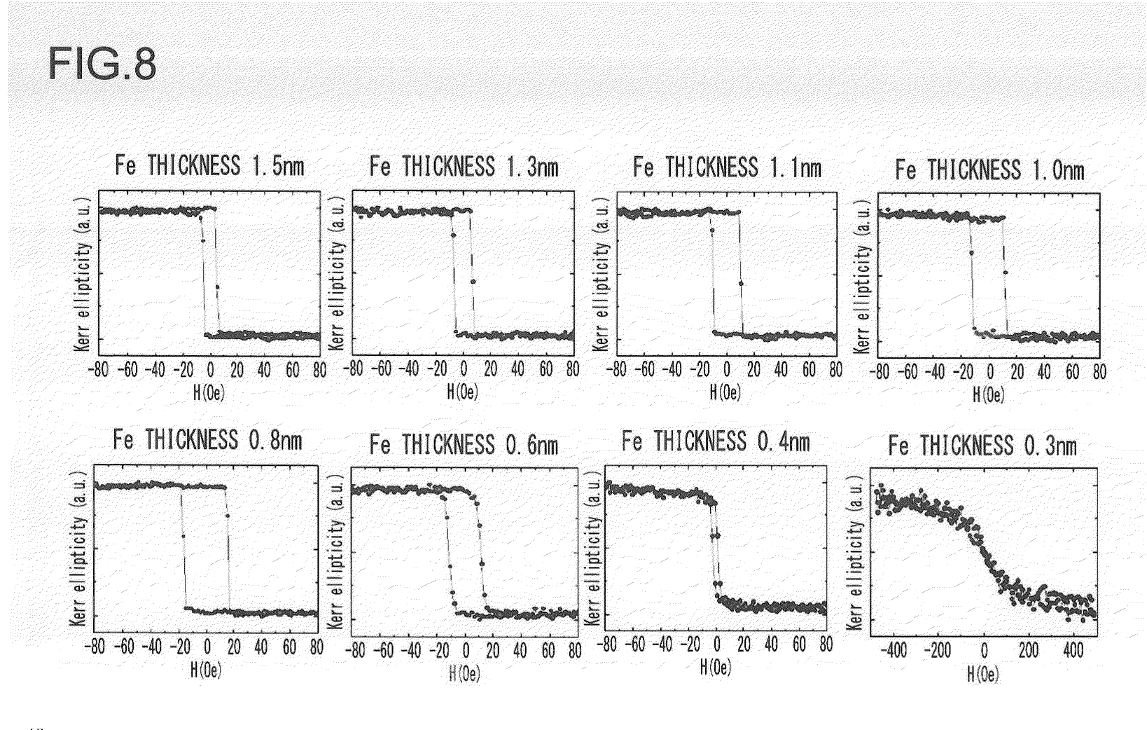

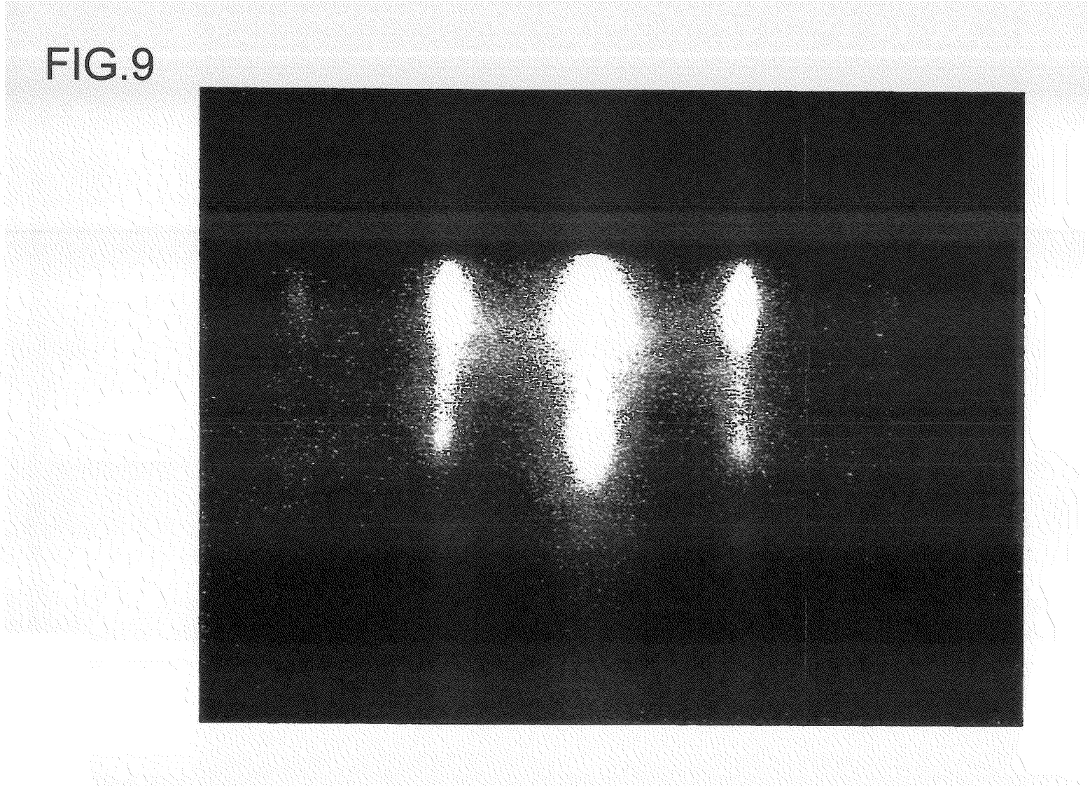

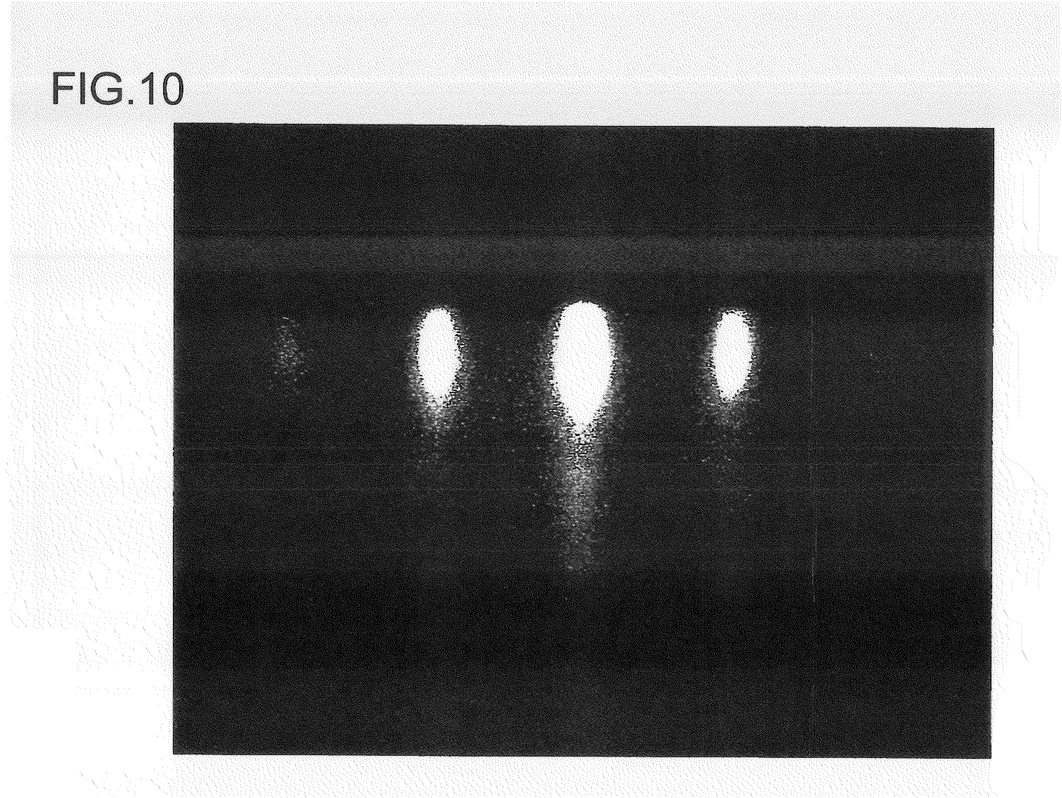

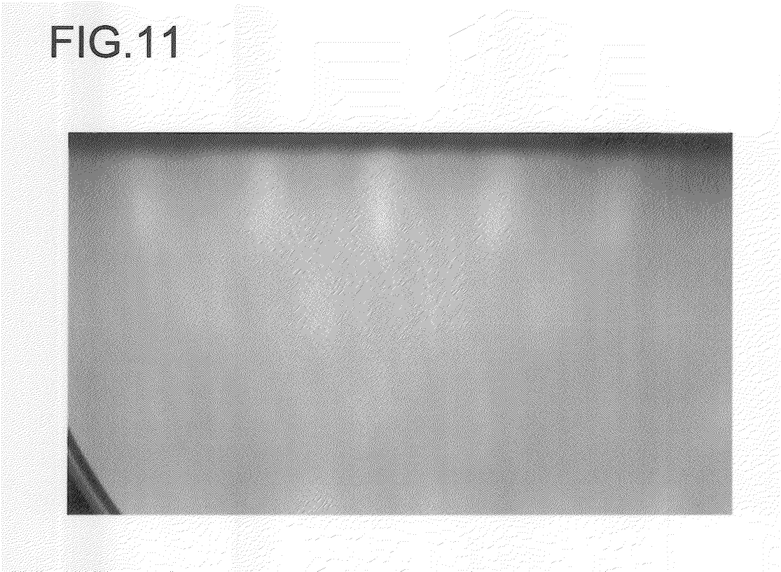

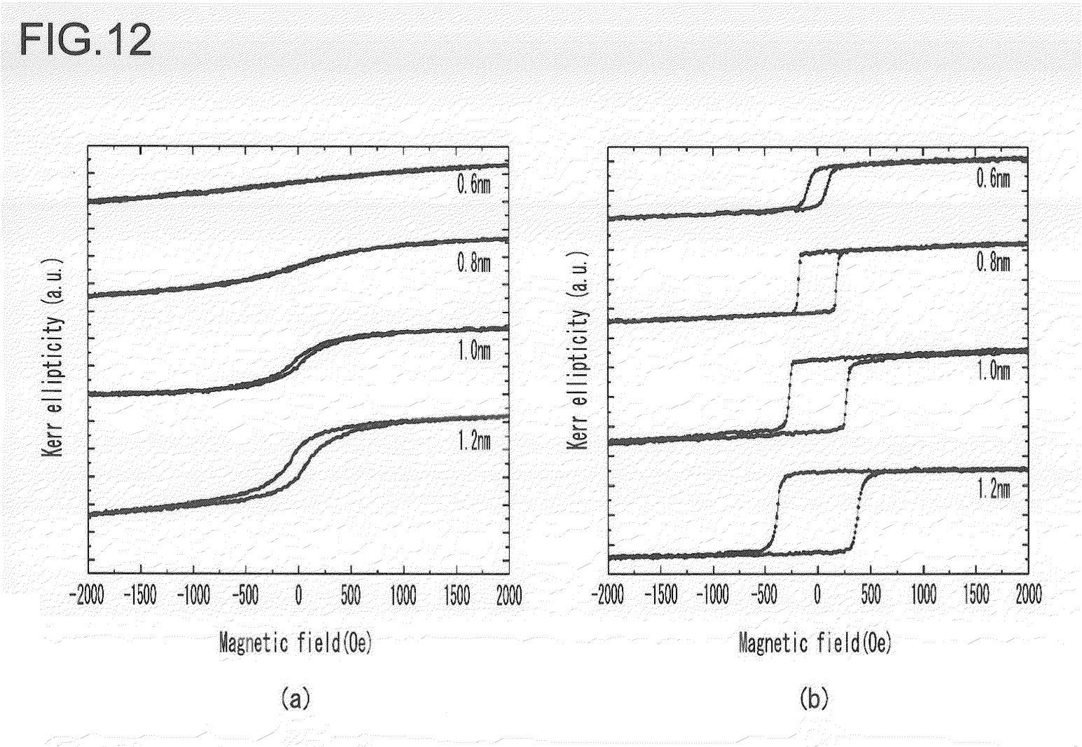

(FIG. 4) FIG. 4 shows a reflection high-energy electron diffraction pattern of an Fe layer (representing an example of a ferromagnetic layer) formed to achieve a thickness of 0.8 nm at room temperature directly upon a single-crystalline magnesium oxide film (nonmagnetic layer, tunnel barrier layer) in which the (001) crystal plane is preferentially oriented.

[FIG. 5] FIG. 5 shows magnetization curves pertaining to Fe layers (each representing an example of a ferromagnetic layer) formed to achieve thicknesses in the range of 0.8 to 1.5 nm at room temperature directly upon a single-crystalline magnesium oxide layer in which the (001) crystal plane is preferentially oriented, graphed through magneto-optical Kerr effect measurement.

[FIG. 6] FIG. 6 shows a reflection high-energy electron diffraction pattern of a maghemite layer (representing an example of an oxide layer) formed to achieve a thickness of 0.3 nm directly upon a single-crystalline magnesium oxide film (nonmagnetic layer, tunnel barrier layer) in which the (001) crystal plane is preferentially oriented.

[FIG. 7] FIG. 7 shows a reflection high-energy electron diffraction pattern of an Fe layer (ferromagnetic layer) formed at room temperature to achieve a thickness of 0.8 nm directly upon a maghemite layer (oxide layer) formed to achieve a thickness of 0.3 nm, laminated directly upon a single-crystalline magnesium oxide layer (nonmagnetic layer, tunnel barrier layer) in which the (001) crystal plane is preferentially oriented.

[FIG. 8] FIG. 8 shows magnetization curves pertaining to Fe layers (ferromagnetic layers) formed at room temperature to achieve thicknesses of 0.3 to 1.5 nm directly upon a maghemite layer (oxide layer) with a 0.3 nm thickness, laminated directly upon a single-crystalline magnesium oxide layer (nonmagnetic layer, tunnel barrier layer) in which the (001) crystal plane is preferentially oriented, graphed through magneto-optical Kerr effect measurement.

[FIG. 9] FIG. 9 shows a reflection high-energy electron diffraction pattern of a Co ferrite layer (representing an example of an oxide layer) formed to achieve a thickness of 0.2 nm directly upon a single-crystalline magnesium oxide film (nonmagnetic layer, tunnel barrier layer) in which the (001) crystal plane is preferentially oriented.

[FIG. 10] FIG. 10 shows a reflection high-energy electron diffraction pattern of an Fe layer (ferromagnetic layer) formed at room temperature to achieve a thickness of 0.5 nm directly upon a Co ferrite layer (oxide layer) formed to achieve a thickness of 0.2 nm, laminated directly upon a single-crystalline magnesium oxide layer (nonmagnetic layer, tunnel barrier layer) in which the (001) crystal plane is preferentially oriented.

[FIG. 11] FIG. 11 shows a reflection high-energy electron diffraction pattern of a BCC Co layer formed to achieve a thickness of 0.8 nm upon a maghemite layer with a 0.4 nm thickness.

[FIG. 12] FIG. 12(a) shows magnetization curves pertaining to BCC Co layers each grown directly upon a magnesium oxide film graphed through magneto-optical Kerr effect measurement, and FIG. 12(b) shows a magnetization curve pertaining to BCC Co layers each grown upon a maghemite layer with a 0.4 nm thickness formed upon a magnesium oxide layer, graphed through magneto-optical Kerr effect measurement.

### DESCRIPTION OF EMBODIMENTS

The following is a detailed description of embodiments of the present invention, given in reference to drawings.

### Embodiment 1

FIG. 1(a) presents a schematic sectional view of a magnetic multilayer film and a TMR element achieved in embodiment 1. Reference numeral 1 indicates a substrate. Reference numeral 2 indicates a base layer. The base layer (2) functions as a “seed layer/buffer layer”, which is used to control the crystal orientation in a ferromagnetic lower electrode layer (3) laminated upon the base layer (2) and to improve the planarity of the ferromagnetic lower electrode layer (3). The base layer (2) is not always required and the ferromagnetic lower electrode layer (3) also functions as the base layer in embodiment 1. Reference numeral 4 indicates a nonmagnetic layer comprising a single-crystalline magnesium oxide in which the (001) crystal plane is preferentially oriented. Reference numeral 5 indicates an extremely thin oxide layer. The oxide layer (5) is disposed on the upper side of the nonmagnetic layer (4), further away from the substrate. Reference numeral 6 indicates an extremely thin ferromagnetic layer (upper electrode layer). The ferromagnetic layer (6) is located upon the oxide layer (5).

As described above, the magnetic multilayer film in the present embodiment includes the nonmagnetic layer (4), the oxide layer (5) and the ferromagnetic layer (6) laminated in this order starting on the side where the substrate (1) is located.

In addition, the ferromagnetic layer (3), which also functions as a lower electrode layer, is disposed on the lower side of the nonmagnetic layer (4), further toward the substrate.

When this magnetic multilayer film is used as an element constituting part of a tunnel magnetoresistive element, the ferromagnetic layer (3) acts as a ferromagnetic lower electrode layer, the nonmagnetic layer (4) acts as a tunnel barrier layer or as part of a tunnel barrier layer, and the ferromagnetic layer (6) acts as a ferromagnetic upper electrode layer or as part of a ferromagnetic upper electrode layer. It is to be noted that the magnesium oxide constituting the nonmagnetic layer (4) may contain, in an appropriate quantity, an element other than oxygen and magnesium.

In the embodiment 1, the oxide layer (5) was formed by using maghemite (Fe₂O₃) and the ferromagnetic layer (6) was formed with Fe.

The individual layers were formed through the molecular beam epitaxy method (MBE method). The layers were formed through MBE by using an ultrahigh vacuum MBE film-forming apparatus capable of achieving an ultimate vacuum of approximately 2×10⁻⁸ Pa.

First, an Fe layer with a thickness of approximately 100 nm was formed on the substrate (1), which Fe layer is a ferromagnetic layer (ferromagnetic lower electrode layer 3) with a BCC (001) structure and also acts as a base layer (2). Then nonmagnetic layer (4) comprising a single-crystalline magnesium oxide (001) was formed upon the Fe layer at room temperature so as to achieve a thickness of approximately 2 nm. It is to be noted that since the presence of a ferromagnetic material in the lower electrode layer would hinder measurement of the magneto-optical Kerr effect, multilayer films used for purposes of measurement of the magneto-optical Kerr effect (see FIG. 6 and FIG. 8) at the ferromagnetic upper electrode layer, as will be explained later, did not include the Fe layer (3) but instead included a Cr layer formed as a nonmagnetic base layer (2) with the BCC (001) structure and with a thickness of approximately 100 nm.

A magnesium oxide (001) layer formed upon a BCC Fe (001) layer and a magnesium oxide (001) layer formed upon a BCC Cr (001) layer achieve qualities and characteristics that substantially match each other.

A maghemite (Fe₂O₃) layer with a thickness of 0.2 to 1.5 nm as the oxide layer (5) was formed upon the nonmagnetic layer (4) comprising the single-crystalline magnesium oxide (001). The maghemite (Fe₂O₃) layer was formed by vapor depositing Fe at a rate of 0.005 nm/s while sustaining the substrate temperature at 130° C. and irradiating the substrate with atomic oxygen at a flow rate of 0.08 sccm. Lastly, an Fe layer was formed at room temperature to achieve a thickness of 0.2 to 2.0 nm as the ferromagnetic layer (ferromagnetic upper electrode layer 6) upon the oxide layer (5).

FIG. 6 provides a reflection high-energy electron diffraction (RHEED) image of a maghemite layer with a 0.3 nm thickness, formed directly upon the single-crystalline magnesium oxide (001) layer. The image includes a clear streaky RHEED pattern indicating that a flat, high quality maghemite layer was formed, having good crystalline characteristics even at such a small thickness. It is worth noting, in particular, that the maghemite layer with a very small thickness of 0.3 nm was formed as a high-quality continuous film directly upon the magnesium oxide (001) layer, the wettability at which is normally very poor. Namely, the maghemite layer achieves good wettability on the surface of the magnesium oxide (001).

The maghemite bulk assumes a spinel-type crystal structure, and the lattice constant of its unit cell is approximately 0.84 nm. This means that if the thickness of a maghemite layer is smaller than the lattice constant of the unit cell in the spinel structure, the structure of the particular maghemite layer cannot be defined as a spinel structure. For instance, the RHEED pattern of the maghemite layer with the 0.3 nm thickness (see FIG. 6) does not include any superlattice lines unique to the spinel structure. The absence of superlattice lines is indicative of the fact that the maghemite layer with the 0.3 nm thickness did not have a superlattice structure unique to the spinel structure.

In contrast, superlattice lines unique to the spinel structure are observed in a RHEED of a maghemite layer with a 2 nm thickness, and accordingly, it is confirmed that a superlattice structure unique to the spinel structure is formed in a maghemite layer with a 2 nm thickness, i.e., a thickness equal to or greater than twice the lattice constant of the unit cell in the spinel structure. This means that the advantage of the present invention is invariably realized regardless of whether or not the superlattice structure unique to the spinel structure is formed, and that the present invention does not require that the superlattice structure unique to the spinel structure be achieved. Accordingly, even a maghemite layer with a thickness smaller than the lattice constant of the unit cell in the spinel structure can be readily utilized as the oxide layer. It is to be noted that since there is no standard term used to refer to a crystal structure of an oxide layer with a thickness smaller than the lattice constant of the unit cell in the spinel structure, as in the case described above, the term “spinel structure” will be used in the description of the present invention also to refer to a crystal structure without the superlattice structure unique to the spinel structure.

FIG. 7 presents a RHEED image of an Fe layer with a 0.8 nm thickness, formed upon the maghemite layer with the 0.3 nm thickness. In contrast to the RHEED image of the Fe layer formed directly upon the magnesium oxide (001) layer (see FIG. 4), the RHEED image in FIG. 7 includes a clear streaky pattern, indicating that a flat, high quality Fe layer was formed even at a small thickness of less than 1 nm. In short, it has been learned that the wettability of the Fe layer is greatly improved by inserting a very thin maghemite layer between the magnesium oxide (001) layer and the Fe layer, as described above.

FIG. 8 presents magnetization curves pertaining to magnetization occurring at room temperature at Fe layers with thicknesses of 0.3 to 1.5 nm, each formed upon a maghemite layer with a 0.3 nm thickness, graphed through magneto-optical Kerr effect measurement. In contrast to the Fe layers formed directly upon the magnesium oxide (001) layer (see FIG. 5), even the Fe layer with a thickness as small as 0.4 nm achieves a good ferromagnetic magnetization curve in FIG. 8. In addition, a ferromagnetic tendency manifests even in the Fe layer having a 0.3 nm thickness, as well. The magnetization measurement results clearly indicate that an Fe layer laminated upon the maghemite layer forms a flat, continuous film when its thickness is equal to or greater than 0.2 nm. These results are in line with the results of the RHEED analysis described earlier.

The observations above may be summarized as follows. The presence of a very thin oxide layer (5) (maghemite layer) inserted between the nonmagnetic layer (4) comprising “magnesium oxide (001)” and the ferromagnetic layer (6) (Fe layer) greatly improves the wettability of the ferromagnetic layer (6) in relation to the nonmagnetic layer (4), and as a result, the ferromagnetic layer (6) can be formed upon the nonmagnetic layer (4) as a flat, high-quality continuous film with a very small thickness. This finding defies a previously accepted view on crystal growth that a very thin flat ferromagnetic layer cannot be formed on a “magnesium oxide (001)” layer with poor wettability. However, the physical mechanisms and the principle of the crystal growth, upon which the crystal growth method adopted in the present invention is based, remain unknown.

It is a critical requirement in applications in which the magnetic multilayer film according to the present invention is used as a component of a TMR element that a large MR ratio be achieved at room temperature. In principle, the MR ratio is reduced when the oxide layer (5) is inserted between the nonmagnetic layer (4) and the ferromagnetic layer (6). However, as long as the oxide layer (5) assumes a small thickness, the reduction in the MR ratio occurs on a limited scale and thus does not give rise to any particular problem. When the thickness of the oxide layer (5) is less than 0.2 nm, however, the average thickness becomes smaller than a single atomic layer and, in such a case, part of the surface of the nonmagnetic layer (4) will no longer be covered with the oxide layer (5) and as a result, the advantage of improved wettability will not be fully realized. If, on the other hand, the oxide layer (5) is too thick, problems such as (i) a significant reduction in the MR ratio and (ii) an excessively large tunnel resistance (RA product) become more pronounced. For these reasons, it is desirable to form the oxide layer (5) so as to achieve a thickness in the range of 0.2 to 1.5 nm, more desirably in the range of 0.2 to 1.0 nm and, even more desirably, in the range of 0.2 to 0.8 nm, 0.2 to 0.6 or 0.2 to 0.4 nm. While it is desirable to minimize the thickness of the oxide layer (5) as far as the MR ratio is concerned, the optimal thickness of the oxide layer (5) must be determined by taking into consideration the need for an improvement in the wettability and the optimal RA product value and the like. In reality, the optimal thickness of the oxide layer (5) will need to be selected in correspondence to various characteristics such as the magnetoresistance ratio and the RA value required for specific applications.

While maghemite is used as the material to constitute the oxide layer (5) in the embodiment 1, the advantage of improved wettability is achieved with an oxide of another 3d transition metal element among various 3d transition metal elements. For instance, an oxide of at least one of Fe, Co and Ni is effective in improving the wettability at the surface of the “magnesium oxide (001)” layer. In addition, an oxide of 3d transition metal element with spinel structure achieving a good lattice match with the “magnesium oxide (001)” layer is particularly effective in improving the wettability at the surface of the “magnesium oxide (001)”. FIG. 9 presents a reflection high-energy electron diffraction (RHEED) image of a Co ferrite layer with a thickness of 0.2 nm formed directly upon a single-crystalline magnesium oxide (001) layer, representing an example of such an oxide. As in the RHEED image of the maghemite layer (see FIG. 6), a clear, streaky RHEED pattern is observed at the very thin Co ferrite layer, indicating that a very thin, flat high quality Co ferrite layer with good crystalline characteristics was formed. This means that the Co ferrite layer assures good wettability on the surface of the “magnesium oxide (001)” layer. In addition, FIG. 10 presents a RHEED image of an Fe layer with a 0.5 nm thickness formed on this Co ferrite layer. As in the RHEED image of the very thin Fe layer formed upon the maghemite (see FIG. 7), a clear, streaky pattern is observed in the RHEED image in FIG. 10, indicating that a flat, high quality Fe layer was formed even at a thickness smaller than 1 nm. In other words, it is demonstrated that a very high level of wettability is achieved by the Fe layer at the surface of the Co ferrite layer. In the embodiment described above, it is shown that the wettability of the “magnesium oxide (001)” layer is greatly improved by forming an oxide layer constituted of an oxide of Fe, Co or the like at the surface of the “magnesium oxide (001)” layer. It is obvious that this advantage can also be achieved by using to use Ni, having chemical properties similar to those of Fe and Co, as the 3d transition metal element in the oxide layer of a 3d transitions metal element. In short, through the use of an oxide of at least one element among Fe, Co and Ni, the wettability of the “magnesium oxide (001)” layer can be effectively improved.

It is also a significant advantage, particularly when the magnetic multilayer film according to the present invention is used as a component of a TMR element that a large MR ratio is achieved at room temperature, as has been described earlier. By forming the oxide layer (5) comprising a spinel ferrite type oxide of 3d transition metal element, the extent to which the MR ratio is reduced can be minimized in comparison to the extent to which the MR ratio is lowered when there is no oxide layer (5). In particular, by forming the oxide layer (5) comprising a “ferromagnetic or ferrimagnetic spinel ferrite material”, an even more significant magnetoresistance effect is achieved due to the spin filter effect attributable to the insulator band structure, resulting from spin polarization. Maghemite used in the embodiment 1 represents an example of the “ferromagnetic or ferrimagnetic spinel ferrite material”. By using maghemite, a large MR ratio of approximately 100% at room temperature was achieved over a layer thickness range of 0.2 to 1.0 nm.

Materials other than maghemite that may be used as the “ferromagnetic or ferrimagnetic spinel ferrite material” include magnetite, Co ferrite and Ni ferrite and the like. Co ferrite and Ni ferrite, each having an extremely high Curie temperature and achieving a significant spin filter effect, are more desirable than maghemite as materials to constitute the oxide layer (5). In addition, magnetite, having a half-metal band structure, is a material effective in achieving a greater MR ratio and a lower RA product. Basically, the optimal materials to constitute the oxide layer (5) is a spinel ferrite type oxide containing oxygen and at least one element among Fe, Co, Ni and the like, with another element added therein as necessary, and that the specific composition of the oxide should be adjusted in correspondence to various characteristics, including the MR ratio and the RA value, required in the particular application. It is to be noted that, as has been explained earlier, the advantages of the present invention will still be realized even if the thickness of the oxide layer comprising the spinel ferrite-type oxide material is smaller than the lattice constant of the unit cell in the spinel structure and thus the superlattice structure unique to the spinel structure is not achieved in the oxide layer.

It is desirable that the material to constitute the ferromagnetic layer (6) (upper electrode layer) be 3d transition metal element or an alloy containing the 3d transition metal element, so as to sustain stable ferromagnetism even at room temperature. In addition, when the magnetic multilayer film according to the present invention is used as a component of a TMR element, a greater MR ratio can be achieved at room temperature by forming the ferromagnetic layer (6) (upper electrode layer) with a ferromagnetic metal or alloy material containing Fe, and even more desirably, by forming the ferromagnetic layer (6) with either a ferromagnetic metal or alloy material that contains Fe and has a BCC structure.

The optimal thickness for the ferromagnetic layer (6) (upper electrode layer) should be selected in correspondence to specific characteristics required in a given application among various applications. In order to satisfy the need for reducing the power consumption in applications such as a spin torque MRAM and a high-frequency oscillator, the thickness of the ferromagnetic layer (6) (upper electrode layer) should be minimized For instance, it is desirable to form the ferromagnetic layer (6) (upper electrode layer) so as to achieve a thickness equal to or less than 0.8 nm, more desirably equal to or less than 0.6 nm and even more desirably equal to or less than 0.4 nm. However, when the thickness of the ferromagnetic layer (6) (upper electrode layer) is less than 0.2 nm, there is bound to be a risk that the surface of the oxide layer (5) cannot be completely covered with the ferromagnetic layer (6) (upper electrode layer). In other words, the ferromagnetic layer (6) (upper electrode layer) needs to achieve a minimum thickness of approximately 0.2 nm. Furthermore, in order to achieve stable ferromagnetism at room temperature, it is desirable to form the ferromagnetic layer (6) (upper electrode layer) to achieve a thickness of 0.3 nm or more and better still, a thickness of 0.4 nm or more. The thickness of the ferromagnetic layer (6) (upper electrode layer) should be selected in correspondence to the requirements of each specific application by prioritizing various requirements, i.e., whether or not top priority is given to reduction of power consumption, whether or not top priority is given to stable ferromagnetism at room temperature, whether or not top priority is given to a higher MR ratio and the like.

While the film is formed through the MBE method in the embodiment 1, the film may instead be formed through a physical vapor deposition (PVD) method such as sputtering or through a chemical vapor deposition (CVD) method. In addition, while atomic oxygen is used in the embodiment 1 as the oxygen source when forming the oxide layer (5), the oxide layer (5) may be formed through an alternative method such as (i) a method in which an oxide of a 3d transition metal element is used as the vapor deposition source material or (ii) a method in which a material containing a 3d transition metal is used for the vapor deposition source material in conjunction with an oxygen source such as molecular oxygen, radical oxygen, plasma oxygen, ozone or the like.

While a single-crystalline magnesium oxide (001) is used to form the nonmagnetic layer (4) in the embodiment 1, the advantageous effect of the present invention should be, in principle, likewise achieved in conjunction with a poly-crystalline magnesium oxide in which the (001) crystal plane is preferentially oriented. Poly-crystalline magnesium oxide is more advantageous than single-crystalline magnesium oxide from the viewpoint of the manufacturing cost.

While, in principle, a single-crystalline magnesium oxide (001) is used to constitute the substrate in the embodiment 1, the substrate may be constituted of any material. A nonmagnetic layer (4) comprising a single- or poly-crystalline magnesium oxide, with the (001) crystal plane is preferentially oriented, can be formed above a specific, optimal type of base layer selected from various base layers, laminated above a given substrate.

### Embodiment 2

FIG. 1(b) presents a schematic sectional view of a magnetic multilayer film and a TMR element achieved in embodiment 2. The embodiment 2 is distinguishable from the embodiment 1 (see FIG. 1(a)) only in that the ferromagnetic layer (6) in the embodiment 1 is replaced by a first ferromagnetic layer (6) and a second ferromagnetic layer (7) in the embodiment 2, and the embodiment 1 and the embodiment 2 are completely identical to each other with regard to other structural components. A very thin first ferromagnetic layer (6) is disposed upon a very thin oxide layer (4) and a second ferromagnetic layer (7) is disposed upon the first ferromagnetic layer (6). If necessary, yet another ferromagnetic layer may be disposed upon the second ferromagnetic layer (7). In addition, a very thin nonmagnetic layer comprising a material such as Ru, Ta, Cu, MgO or the like may be inserted between the first ferromagnetic layer (6) and the second ferromagnetic layer (7) as needed. By laminating two or more ferromagnetic layers one upon the other, as illustrated in FIG. 1(b), the magnetic characteristics and the MR ratio can be optimized to meet the needs of a particular application. For instance, when the magnetic multilayer film according to the present invention is to be used as a component in a TMR element, a high MR ratio and the desired magnetic characteristics can be achieved at once by forming the first ferromagnetic layer (6) with a material having a high MR ratio, forming the second ferromagnetic layer (7) with a material having the desired magnetic characteristics and allowing these two layers to behave as a single ferromagnetic layer (upper electrode layer) through the exchange coupling occurring at the interface between the two layers.

It is desirable that the material to constitute the first ferromagnetic layer (6) be 3d transition metal element or an alloy containing the 3d transition metal element, so as to sustain stable ferromagnetism even at room temperature. In addition, when the magnetic multilayer film according to the present invention is used as a component of a TMR element, a greater MR ratio can be achieved at room temperature by forming the first ferromagnetic layer (6) with a ferromagnetic metal material containing Fe or a ferromagnetic alloy material containing Fe, and even more desirably, by forming the ferromagnetic layer (6) with either a ferromagnetic metal or alloy material that contains Fe and has a BCC structure.

The optimal thickness for the first ferromagnetic layer (6) should be selected in correspondence to specific characteristics required in a given application among various applications. In order to satisfy the need for reducing the power consumption in applications such as a spin torque MRAM and a high-frequency oscillator, the thickness of the first ferromagnetic layer (6) should be minimized For instance, it is desirable to form the first ferromagnetic layer (6) so as to achieve a thickness equal to or less than 0.8 nm, more desirably equal to or less than 0.6 nm and even more desirably equal to or less than 0.4 nm. However, when the thickness of the first ferromagnetic layer (6) is less than 0.2 nm, there is bound to be a risk that the surface of the oxide layer (5) cannot be completely covered with the first ferromagnetic layer (6). In other words, the first ferromagnetic layer (6) needs to achieve a minimum thickness of approximately 0.2 nm. Furthermore, in order to achieve stable ferromagnetism at room temperature, it is desirable to form the first ferromagnetic layer (6) to achieve a thickness of 0.3 nm or more and better still a thickness of 0.4 nm or more. The thickness of the first ferromagnetic layer (6) should be selected in correspondence to the requirements of each specific application by prioritizing various requirements, i.e., whether or not top priority is given to reduction of power consumption, whether or not top priority is given to stable ferromagnetism at room temperature, whether or not top priority is given to a higher MR ratio and the like.

By forming the second ferromagnetic layer (7) with a soft magnetic material such as Permalloy, soft magnetic characteristics can be rendered in the multilayer laminate made up with the first ferromagnetic layer (6) and the second ferromagnetic layer (6). For instance, when the magnetic multilayer film in the embodiment 2 is utilized as a component of a TMR element, soft magnetic characteristics rendered at the ferromagnetic upper electrode layer will make it possible to realize a device engaged in operation with an even smaller magnetic field applied thereto or an even smaller spin torque applied thereto.

By forming the second ferromagnetic layer (7) with a perpendicular magnetic material or a perpendicular magnetic anisotropic material, perpendicular magnetic characteristics can be rendered for the multilayer laminate made up with the first ferromagnetic layer (6) and the second ferromagnetic layer (7). For instance, a TMR element having as a component thereof the magnetic multilayer film in the embodiment 2 with perpendicular magnetic characteristics rendered at the ferromagnetic upper electrode layer can be used in a highly integrated spin torque MRAM. Examples of perpendicular magnetic materials and perpendicular magnetic anisotropic materials that may be used in such applications include an alloy with an L1₀-ordered structure such as Fe—Pt, Fe—Pd, Co—Pt, Co—Pd, Mn—Ga, or the like, a multilayer film formed by laminating a ferromagnetic metal or an alloy containing a ferromagnetic metal and a nonmagnetic metal or an alloy containing a nonmagnetic metal, an alloy containing 3d transition metal element and a rare earth metal such as Tb—Co or Tb—Fe—Co, a metal material with an HCP structure containing Co or an alloy containing such a metal, and a thin Co—Fe—B alloy layer formed by taking advantage of perpendicular magnetic anisotropy manifesting at the interface.

By inserting a nonmagnetic layer comprising, for instance, ruthenium (Ru) with an optimal thickness between the first ferromagnetic layer (6) and the second ferromagnetic layer (7), the magnetization of the first ferromagnetic layer (6) and the magnetization of the second ferromagnetic layer (7) can be oriented so that the magnetization directions run anti-parallel to each other. Through these measures, the extent of magnetic field leak from the multilayer laminate made up with the first ferromagnetic layer (6) and the second ferromagnetic layer (7) can be reduced.

By interrupting the exchange coupling between the first ferromagnetic layer (6) and the second ferromagnetic layer (7) with a nonmagnetic layer inserted between them, and by forming either the first ferromagnetic layer (6) or the second ferromagnetic layer (7) with an in-plane magnetic material and the other with a perpendicular magnetic material, the angle of magnetization of the first ferromagnetic layer (6) relative to the magnetization of the second ferromagnetic layer (7) can be set to approximately 90°. As a result, the operating current density can be reduced in applications such as high-frequency oscillators and the like.

### Embodiment 3

While the ferromagnetic layer (6) is formed with Fe in the embodiment 1, Co is used to form the ferromagnetic layer (6) in this embodiment. In the related art, it is known to be difficult to grow and form a film with a BCC Co layer, which is a metastable crystal layer, upon a nonmagnetic layer (4) comprising a material such as magnesium oxide. The magnetic multilayer film in this embodiment was manufactured by forming in advance an oxide layer (5), comprising an extremely thin maghemite layer with a 0.4 nm thickness upon the nonmagnetic layer (4) and then forming a ferromagnetic layer (6) constituted with an extremely thin BCC Co layer with a thickness of approximately 0.8 nm upon the oxide layer (5).

As a result, the BCC Co layer grew in a desirable manner and an improvement in the wettability was achieved. As an example of such a BCC Co layer, FIG. 11 presents a RHEED (reflection high-energy electron diffraction) image of a BCC Co layer formed so as to achieve a thickness of 0.8 nm upon a maghemite layer with a 0.4 nm thickness. The RHEED image includes a streaky pattern indicating the preferred orientation in the BCC structure, which proves that a flat ferromagnetic layer (6) constituted with an extremely thin BCC Co film layer can be formed (via a maghemite layer) above the nonmagnetic layer (4). FIG. 12 indicates for purposes of comparison, the magnetic characteristics achieved with BCC Co layers grown to form films directly upon a magnesium oxide layer, i.e., the nonmagnetic layer (4). Even when the thickness of a BCC Co layer grown directly upon the nonmagnetic layer (4) is as thick as 1.2 nm, a hysteresis with poor angularity manifests (see FIG. 12(a)). Moreover, once the thickness of the BCC Co layer becomes equal to or less than 0.8 nm, superparamagnetic behavior, which reflects a growth of a BCC Co layer in island shaped areas, is observed.

In contrast, when the BCC Co layer is grown on a maghemite layer with a 0.4 nm thickness (see FIG. 12(b)), a hysteresis with good angularity is achieved even at a very small film thickness of 0.8 nm, demonstrating the crystal magnetic anisotropy of the BCC Co (001) layer that is formed by epitaxial growth, and furthermore, it is proved that the ferromagnetic characteristics are sustained even at a BCC Co layer thickness of 0.6 nm BCC Co layers are known to manifest higher magnetoresistive characteristics in comparison to Fe layers, and the process according to the present invention through which the ferromagnetic layer (6) constituted with an extremely thin BCC Co layer is formed upon the nonmagnetic layer (4) is highly effective in improving the characteristics of TMR elements.

While various embodiments and variations thereof are described above, the present invention is in no way limited to the particulars of these examples. Any other modes conceivable within the scope of the technical concept of the present invention are also within the scope of the present invention.

The disclosure of the following priority application is herein incorporated by reference:

Japanese Patent Application No. 2012-192115 filed Aug. 31, 2012.

### REFERENCE SIGNS LIST

1 . . . substrate
2 . . . base layer
3 . . . lower ferromagnetic layer (ferromagnetic lower electrode layer)
4 . . . nonmagnetic layer (tunnel barrier layer or part thereof)
5 . . . oxide layer of 3d transition metal element
6 . . . upper ferromagnetic layer or first ferromagnetic layer (ferromagnetic upper electrode layer or part thereof)
7 . . . second ferromagnetic layer (ferromagnetic upper electrode layer or part thereof)
8 . . . cap layer
33 . . . lower electrode layer
34 . . . nonmagnetic layer (tunnel barrier layer or part thereof)
36 . . . ferromagnetic layer or first ferromagnetic layer

1. A magnetic multilayer film comprising in sequence starting on a substrate side:
a nonmagnetic layer comprising a single- or poly-crystalline magnesium oxide in which a (001) crystal plane is preferentially oriented;
an oxide layer with a thickness of 0.2 to 1.5 nm comprising an oxide of 3d transition metal element; and
a ferromagnetic layer as a continuous film with a thickness of 0.3 to 0.8 nm.

2. The magnetic multilayer film according to claim 1, wherein:
assuming that the ferromagnetic layer is a first ferromagnetic layer,
a second ferromagnetic layer is formed on the first ferromagnetic layer,
which second ferromagnetic layer has a composition or a crystal structure different from the first ferromagnetic layer.

3. (canceled)

4. The magnetic multilayer film according to claim 1, wherein:
the 3d transition metal element is at least one element of among Fe, Co and Ni.

5. A magnetic multilayer film comprising in sequence starting on a substrate side:
a nonmagnetic layer comprising a single- or poly-crystalline magnesium oxide in which a (001) crystal plane is preferentially oriented;
a very thin oxide layer comprising an oxide with a spinel structure of 3d transition metal element; and
a very thin ferromagnetic layer.

6. A magnetic multilayer film comprising in sequence starting on a substrate side:
a nonmagnetic layer comprising a single- or poly-crystalline magnesium oxide in which a (001) crystal plane is preferentially oriented;
a very thin oxide layer comprising an oxide with a spinel ferrite type structure of 3d transition metal element; and
a very thin ferromagnetic layer.

7. The magnetic multilayer film according to claim 6, wherein:
the oxide with a spinel ferrite type structure is a ferromagnetic spinel ferrite material or a ferrimagnetic spinel ferrite material.

8. A magnetic multilayer film, comprising:
a nonmagnetic layer comprising a single- or poly-crystalline magnesium oxide in which a (001) crystal plane is preferentially oriented;
a very thin oxide layer comprising a maghemite, magnetite, Co ferrite or Ni ferrite; and
a very thin ferromagnetic layer.

9. (canceled)

10. A magnetic multilayer film according to claim 1, wherein:
the ferromagnetic layer comprises
a ferromagnetic metal containing Fe, or
a ferromagnetic alloy containing Fe.

11. A magnetic multilayer film according to claim 1, wherein:
the ferromagnetic layer comprises
a ferromagnetic metal with a BCC structure containing Fe or Co, or
a ferromagnetic alloy with a BCC structure containing Fe or Co.

12. A tunnel magnetoresistive element comprising a ferromagnetic lower electrode layer, a tunnel barrier layer and a ferromagnetic upper electrode layer in sequence starting on a substrate side, wherein:
the magnetic multilayer film according to claim 1 constitutes a part of the tunnel magnetoresistive element, in which
the nonmagnetic layer according to claim 1 corresponds to the tunnel barrier layer(s) or part thereof and
the ferromagnetic layer according to claim 1 corresponds to the upper electrode layer or part thereof.

13. The magnetic multilayer film according to claim 2, wherein the 3d transition metal element is at least of one element among Fe, Co and Ni.
